(19) United States
(12) Patent Application Publication
(10) Pub. No.: US 2025/0027998 A1
(43) Pub. Date: Jan. 23, 2025

(54) ELECTRONIC DEVICE AND BATTERY POWER DISPLAYING METHOD THEREOF

(71) Applicant: ASUSTeK COMPUTER INC., Taipei City (TW)

(72) Inventors: Shih-Teng Chiu, Taipei City (TW); Hui-Hsiang Lin, Taipei City (TW); Chih-Hung Lee, Taipei City (TW); Chia-Yuan Chang, Taipei City (TW); Po-Chun Chen, Taipei City (TW); Chih-Hsiang Chiu, Taipei City (TW)

(73) Assignee: ASUSTeK COMPUTER INC., Taipei City (TW)

(21) Appl. No.: 18/528,793

(22) Filed: Dec. 5, 2023

(30) Foreign Application Priority Data
Jul. 20, 2023 (TW) 112127100

(51) Int. Cl. G01R 31/36; G01R 19/165; G01R 31/367; G01R 31/3842

(52) U.S. Cl. CPC G01R 31/3646; G01R 19/16542; G01R 31/3648; G01R 31/367; G01R 31/3842

(57) ABSTRACT

An electronic device and a battery power displaying method of the electronic device are provided. The method includes following steps. Estimated power of a battery module in the electronic device is obtained. A slope parameter is adjusted according to a charging and discharging state of the electronic device and the estimated power. The estimated power is converted into mapping power based on the slope parameter. The mapping power is disposed on a user interface.

### CROSS-REFERENCE TO RELATED APPLICATION

This application claims the priority benefit of Taiwan application serial no. 112127100, filed on Jul. 20, 2023. The entirety of the above-mentioned patent application is hereby incorporated by reference herein and made a part of this specification.

### BACKGROUND

### Technical Field

The disclosure relates to an electronic device capable of optimizing a display of battery power and a battery power display method of the electronic device.

### Description of Related Art

In existing handheld electronic products, such as laptops, mobile phones, digital cameras, tablets, or the like, a battery plays a crucial role in power supply. However, power calculated by a battery gauge IC currently available in the market is somewhat uncertain. This may lead to calculation errors and result in rapid fluctuations in an estimated power level. For instance, a sudden drop from 30% to 29% may merely take 5 seconds, or a jump or drop of more than 2% (e.g., from 50% to 52% or even directly from 3% remaining to 0%) may be shown. This not only impacts the overall system stability but also causes users to perceive abnormal power situations, thus leading to a subpar user experience.

### SUMMARY

An embodiment of the disclosure provides a battery power displaying method adapted to an electronic device including a battery module. The method includes following steps. Estimated power of the battery module is obtained. A slope parameter is adjusted according to a charging and discharging state of the electronic device and the estimated power. The estimated power is converted into mapping power based on the slope parameter. The mapping power is displayed on a user interface.

An embodiment of the disclosure also provides an electronic device that includes a battery module, a display device, a memory, and a processor. The battery module includes a battery cell group and a control circuit. The control circuit is configured to calculate estimated power of the battery module. The display device is configured to display a user interface. The memory is configured to store a programing command. The processor is coupled to the battery module, the display device, and the memory and loads and executes the programing command to: obtain the estimated power of the battery module from the control circuit, adjust a slope parameter according to a charging and discharging state of the electronic device and the estimated power, convert the estimated power into mapping power based on the slope parameter, and display the mapping power on the user interface through the display device.

In view of the above, the electronic device and the battery power displaying method thereof provided in one or more embodiments of the disclosure may dynamically adjust the slope parameter according to the current state, and the adjusted slope parameter may be applied to convert the estimated power into the mapping power. Thereby, it is possible to customize a charging and discharging curve, avoid the excessively rapid battery power change or power jumps/drops, increase the stability of the system, and provide a better user experience.

Several exemplary embodiments accompanied with figures are described in detail below to further describe the disclosure in details.

### BRIEF DESCRIPTION OF THE DRAWINGS

The accompanying drawings are included to provide a further understanding of the disclosure, and are incorporated in and constitute apart of this specification. The drawings illustrate exemplary embodiments of the disclosure and, together with the description, serve to explain the principles of the disclosure.

FIG. 1 is a schematic block view illustrating an electronic device according to an embodiment of the disclosure.

FIG. 2 is a flowchart illustrating a battery power displaying method according to an embodiment of the disclosure.

FIG. 3 is a flowchart illustrating a battery power displaying method according to an embodiment of the disclosure.

FIG. 4 is a flowchart illustrating a battery power displaying method according to an embodiment of the disclosure.

### DESCRIPTION OF THE EMBODIMENTS

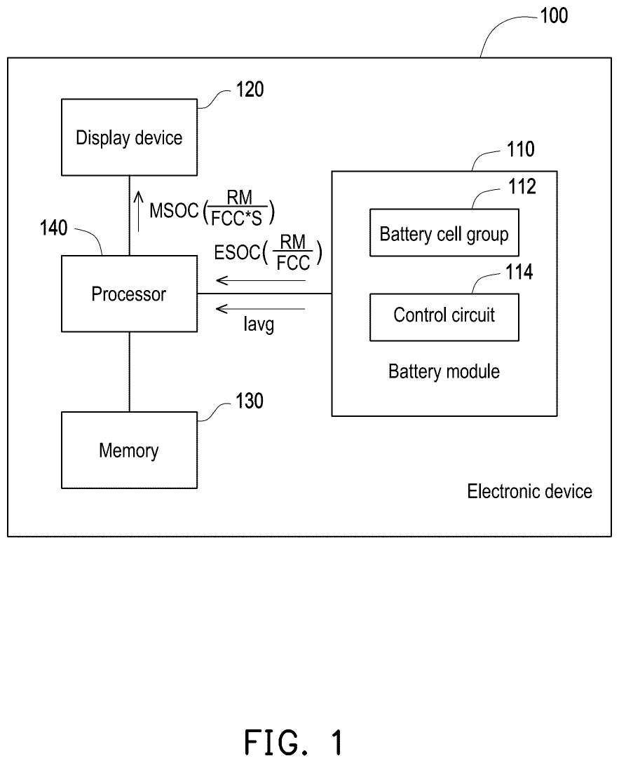

With reference to FIG. 1, an electronic device 100 provided in this embodiment is, for instance, a handheld electronic product, such as a laptop, a mobile phone, a digital camera, or a tablet. The electronic device 100 includes a battery module 110, a display device 120, a memory 130, and a processor 140.

The battery module 110 may be configured to power the electronic device 100 and may be either embedded or externally connected. The battery module 110 includes a battery cell group 112 and a control circuit 114. The battery cell group 112 is composed of one or more battery cells (battery cell monomers), for instance. The control circuit 114 may include a battery gauge IC, which may be configured to calculate estimated power ESOC of the battery module 110 and an average current Iavg during charging and discharging.

The display device 120, for instance, is a liquid crystal display (LCD), a light-emitting diode (LED) display, a field emission display (FED), or any other display having any other type of panel. The display device 120 may be configured to display a user interface, to convey messages or information to the user through the user interface, or to receive specific operations from the user.

The memory 130, for instance, is any type of fixed or movable random access memory (RAM), read-only memory (ROM), flash memory, hard disk, or any other similar device, integrated circuit, and a combination thereof. The memory 130 may be configured to store programming commands including data, programming codes, and a combination thereof.

The processor 140, for instance, is a central processing unit (CPU) or any other programmable general-purpose or special-purpose microprocessor, digital signal processor (DSP), programmable controller, application specific integrated circuit (ASIC), any other similar component, or a combination of the above components.

As shown in FIG. 1, the processor 140 is coupled to the battery module 110, the display device 120, and the memory 130. The processor 140 may load and execute the programming commands stored in the memory 130 to perform the battery power displaying method provided in one or more embodiments of the disclosure.

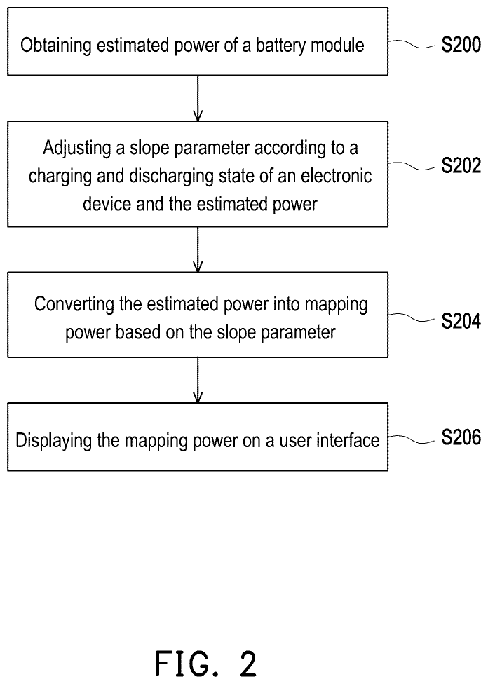

Detailed steps of the battery power displaying method provided in one or more embodiments of the disclosure are described in the following embodiments. Please refer to FIG. 1 and FIG. 2 at the same time. The battery power displaying method provided in this embodiment is adapted to the electronic device 100 in FIG. 1, and the steps of the method are described as follows.

Firstly, in step S200, the processor 140 obtains the estimated power ESOC of the battery module 110 from the control circuit 114. Specifically, the estimated power ESOC is obtained by dividing a remaining capacity RM of the battery module 110 by a full charge capacity (i.e., the capacity FCC of the fully charged battery module 110). The estimated power ESOC may be represented in formula (1) below:

$$ESOC = RM / FCC \qquad ( 1 )$$

The control circuit 114 may, for instance, execute a firmware algorithm provided by a battery supplier to estimate the power of the battery module 110, so as to send the remaining capacity RM and the full charge capacity FCC of the battery module 110 to the processor 140.

Next, in step S202, the processor 140 adjusts a slope parameter S according to the charging and discharging state of the electronic device 100 and the estimated power ESOC. In step S204, the processor 140 converts the estimated power ESOC into mapping power MSOC based on the slope parameter S. Specifically, the processor 140 may multiply the full charge capacity FCC by the slope parameter S to obtain a parameter capacity (FCC*S) and divide the remaining capacity RM by the parameter capacity to obtain the mapping power MSOC. The mapping power MSOC may be represented in formula (2) below:

$$MSOC = RM / ( FCC * S ) = ESOC * ( 1 / S ) \qquad ( 2 )$$

Finally, in step S206, the processor 140 displays the mapping power MSOC on the user interface through the display device 120.

During the operation of the electronic device 100, note that the processor 140 repeatedly executes the battery power displaying method provided in one or more embodiments of the disclosure (i.e., the steps shown in FIG. 2) at intervals of a predetermined cycle, so as to dynamically adjust the slope parameter S and continuously update the mapping power MSOC displayed on the user interface.

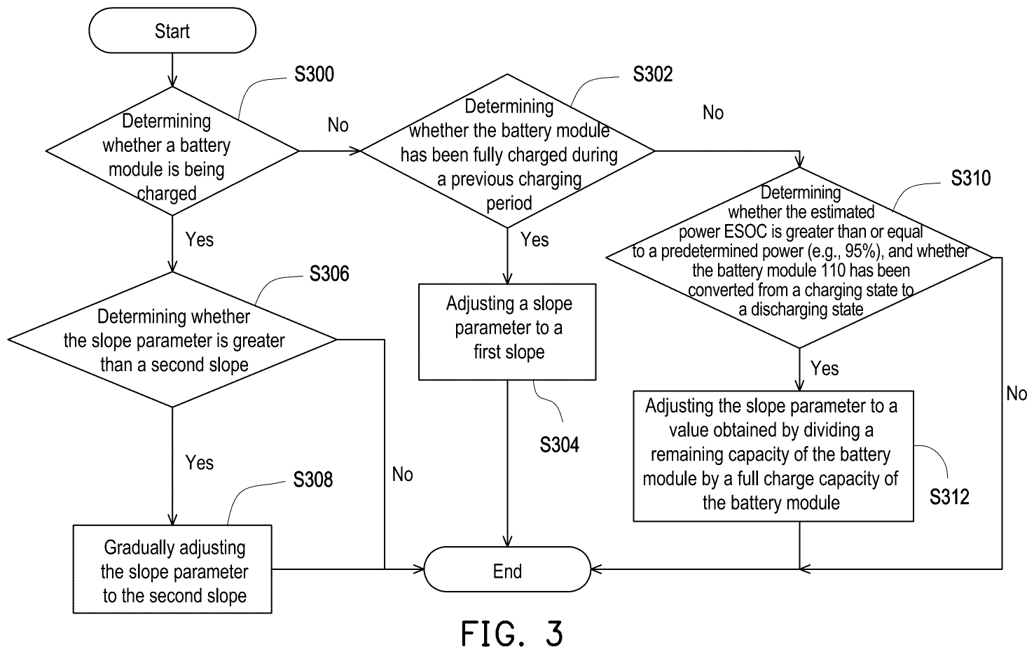

A detailed implementation manner of adjusting the slope parameter S in step S202 shown in FIG. 2 may refer to the steps in FIG. 3. Please refer to FIG. 1 and FIG. 3. First, in step S300, the processor 140 determines whether the battery module 110 is being charged. When the battery module 110 is not being charged (during discharging), in step S302, the processor 140 determines whether the battery module 110 has been fully charged during the previous charging period. Specifically, when the battery module 110 has been fully charged during the charging period, the processor 140 sets a power maintenance flag to logic 1. When the battery module 110 has not been fully charged during the charging period, the processor 140 resets the power maintenance flag to logic 0. Therefore, during the subsequent discharging period, the processor 140 may determine whether the power maintenance flag is set to logic 1. If the power maintenance flag is set to logic 1, it indicates that the battery module 110 has been fully charged during the previous charging period. If the power maintenance flag is not set to logic 1, it indicates that the battery module 110 has not been fully charged during the previous charging period.

When the battery module 110 has been fully charged during the previous charging period, in step S304, the processor 140 adjusts the slope parameter S to a first slope. In this embodiment, the first slope is, for instance, 98.5%, and at this time the mapping power MSOC is obtained by multiplying the estimated power ESOC by 101.5% (100/98.5). In other words, the estimated power ESOC has to drop below 98.5% before the mapping power MSOC starts to become less than 100%, thus providing an extra 1.5% capacity space. As such, even if the battery module 110 has started to discharge, the mapping power MSOC displayed on the user interface to the user remains at 100% within a certain capacity space and does not drop immediately. Thereby, a discharging curve of the battery module 110 may be customized without changing the original firmware algorithm of the battery module 110.

In this embodiment, when the calculated mapping power MSOC is greater than or equal to 100%, note that the mapping power MSOC displayed on the user interface still remains at 100%.

When the processor 140 determines in step S300 that the battery module 110 is being charged (during the charging period), the processor 140 determines in step S306 whether the slope parameter S is greater than a second slope. In this embodiment, the second slope is less than the first slope and is, for instance, 95%. If the slope parameter S is not greater than the second slope, the processor 140 does not change the slope parameter S and continues to adopt the current slope.

If the slope parameter S is greater than the second slope, then in step S308, the processor 140 gradually adjusts the slope parameter S to the second slope. If it is assumed that the current slope parameter S is 100%, and if the slope parameter S is directly adjusted to 95%, note that the mapping power MSOC may accordingly instantly increase by 5% and result in a jump/drop. To avoid such a jump/drop, the processor 140 may determine an adjustment amount a of the slope parameter S based on a current average current Iavg of the battery module 110, so as to gradually adjust the slope parameter S to the second slope. For instance, the control circuit 114 in the battery module 110 may collect the current value of charging or discharging every 0.25 second. After the control circuit 114 collects 4 current values at the intervals of 0.25 second, the average of the 4 current values may be taken as the average current Iavg for the current second.

Table 1 below provides an example of a corresponding relationship between the average current Iavg and the adjustment amount a.

TABLE 1

| Iavg | <200 mA | 200~300 mA | 300~400 mA | >400 mA |
|---|---|---|---|---|
| α | 0.05% | 0.1% | 0.15% | 0.2% |

Table 1 lists four adjustment amounts a corresponding to different ranges of the average current Iavg. The processor 140 may subtract the corresponding adjustment amount a from the slope parameter S at intervals of a predetermined time until the slope parameter S equals the second slope. For instance, when the average current Iavg is within the range of less than 200 milliamperes, the processor 140 subtracts 0.05% from the slope parameter S at intervals of the predetermined time until the slope parameter S equals 95%. When the average current Iavg is within the range of 200 milliamperes to 300 milliamperes, the processor 140 subtracts 0.1% from the slope parameter S at intervals of the predetermined time until the slope parameter S equals 95%, and the rest may be deduced therefrom. As such, the mapping power MSOC may eventually be obtained by multiplying the estimated power ESOC by (100/95) during the charging period, so that when the estimated power ESOC reaches 95% due to charging, the mapping power MSOC displayed on the user interface is 100%. Thereby, a charging curve of the battery module 110 may be customized without changing the original firmware algorithm of the battery module 110.

Note that the corresponding relationship between the average current Iavg and the adjustment amount a listed in Table 1 is generated based on the actual test results under specific scenarios. Those skilled in the art may calculate and estimate the appropriate corresponding relationship according to actual usage scenarios and demands with reference to the teachings provided in this embodiment.

On the other hand, when the processor 140 determines in step S302 that the battery module 110 has not been fully charged during the previous charging period, the processor 140 determines in step S310 whether the estimated power ESOC is greater than or equal to a predetermined power (e.g., 95%), and whether the battery module 110 has been converted from a charging state to a discharging state. For instance, the processor 140 repeatedly execute the battery power displaying method provided in one or more embodiments of the disclosure at intervals of a predetermined cycle. When the battery module 110 is converted from a charging state to a discharging state, the processor 140 determines that the battery module 110 is being charged during the previous execution of step S300 and determines that the battery module 110 is being discharged during the current execution of step S300. The processor 140 may keep relevant records of the charging and discharging state of the battery module 110 for confirmation.

When the estimated power ESOC is not greater than nor equal to the predetermined power, or when the battery module 110 is not converted from the charging state to the discharging state, the processor 140 does not change the slope parameter S and continues to adopt the current slope.

When the estimated power ESOC is greater than or equal to the predetermined power, and the battery module 110 is converted from the charging state to the discharging state, the processor 140 adjusts the slope parameter S in step S312 to a value obtained by dividing the remaining capacity RM of the battery module 110 by the full charge capacity FCC of the battery module 110, and the value is equal to the estimated power ESOC. Therefore, the mapping power MSOC at this time equals 100% obtained by multiplying the estimated power ESOC by the reciprocal of the estimated power ESOC. Thereby, the current estimated power ESOC may serve as the 100% mapping power MSOC for power mapping. As such, the discharging curve of the battery module 110 may be customized, thus allowing the mapping power MSOC to decrease from 100% during the discharging period.

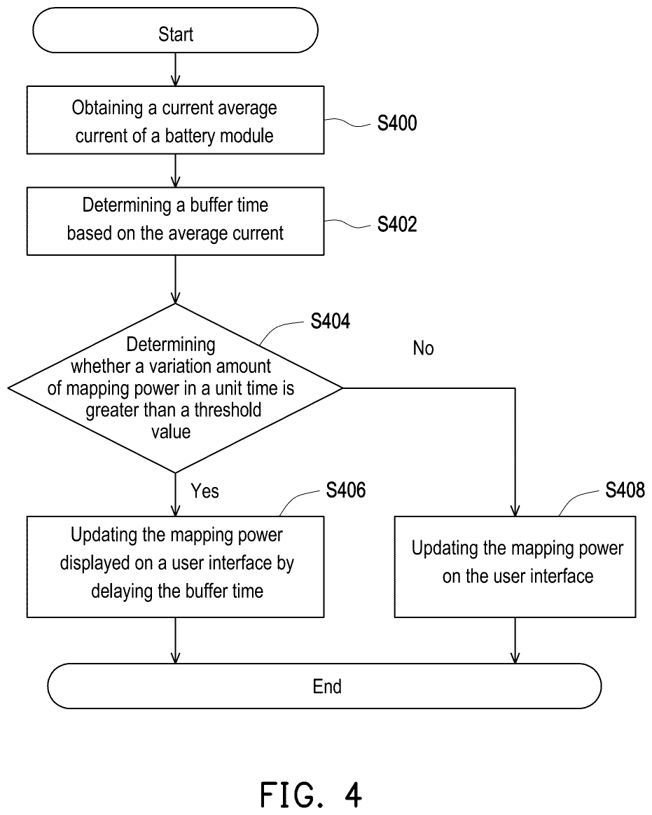

If it is assumed that the mapping power MSOC changes in an excessively rapid manner, e.g., drops from 30% to 29% in 5 seconds, but the system of the electronic device 100 is not in an overload situation, users may easily notice that the battery power of the battery module 110 is consumed too quickly. In addition, in the case of a jump/drop in the mapping power MSOC (e.g., the power drops from 3% to 0%, which causes the system to shut down, or the power jumps from 96% to 100%, which stops the charging operation), not only does it seriously affect the stability of the system, but it also makes the users using the user interface perceive abnormal power. Therefore, in an embodiment of the disclosure, the processor 140 may buffer the increase or decrease of the mapping power MSOC based on the average current Iavg to avoid overly fast speed of power change or the jump/drop. In detail, the step of displaying the mapping power MSOC on the user interface in FIG. 2 (step S206) may include steps S400, S402, S404, and S406 in FIG. 4. Please refer to FIG. 1 and FIG. 4. In step S400, the processor 140 obtains the current average current Iavg of the battery module 110 from the control circuit 114. In step S402, the processor 140 determines a buffer time Tb based on the average current Iavg. The following Table 2 provides an example of a corresponding relationship between the buffer time Tb and the average current Iavg during charging and discharging.

TABLE 2

| Tb | 10 s | 20 s | 30 s | 40 s | 60 s |
|---|---|---|---|---|---|
| Iavg | >3000 mA | >2000 mA | >1000 mA | N/A | 0 mA~1000 mA |
| during | | | | | |
| charging | | | | | |
| Iavg | <−1500 mA | <−1000 mA | <−500 mA | <−300 mA | 0 mA~−300 mA |
| during | | | | | |
| discharging | | | | | |

Table 2 lists five types of buffer times Tb corresponding to different ranges of the average current Iavg during charging and discharging. For instance, when the average current Iavg during discharging is within the range of less than −1500 milliamperes, the buffer time Tb is 10 seconds. When the average current Iavg during discharging is within the range of less than −1000 milliamperes, the buffer time Tb is 20 seconds, and the rest may be deduced therefrom. Note that the corresponding relationship between the average current Iavg and the buffer time Tb listed in Table 2 is generated based on the actual test results under specific scenarios. Those skilled in the art may calculate and estimate the appropriate corresponding relationship according to actual usage scenarios and demands with reference to the teachings provided in this embodiment.

In step S404, the processor 140 determines whether a variation amount of the mapping power MSOC in a unit time (e.g., 5 seconds) is greater than a threshold value (e.g., 1%), and the threshold value may be set based on the average current Iavg during charging and discharging. If the variation amount of the mapping power MSOC in the unit time is greater than the threshold value, then in step S406, the processor 140 updates the mapping power MSOC displayed on the user interface through the display device 120 by delaying the buffer time Tb.

For instance, when a numerical value of the mapping power MSOC increases or decreases from a first percentage to a second percentage in a unit time (the variation amount between the second percentage and the first percentage is greater than the threshold value), the processor 140 may continuously increase or decrease the numerical value of the mapping power MSOC from the first percentage (before the numerical value is changed) by a predetermined amount (e.g., 1%) at intervals of every determined buffer time Tb, and the processor 140 sequentially updates the numerical value displayed on the user interface until the numerical value increases or decreases to the second percentage after the numerical value is changed. Specifically, when the numerical value of the mapping power MSOC increases from 50% to 52% in 5 seconds, and the determined buffer time Tb is 30 seconds, the processor 140 may update the numerical value of the mapping power MSOC displayed on the user interface sequentially as 50%, 51%, and 52% at intervals of every 30 seconds.

If the variation amount of the mapping power MSOC in the unit time is not greater than the threshold value, then in step S408, the processor 140 updates the mapping power MSOC displayed on the user interface through the display device 120.

Through the above method, it is possible to buffer the increase or decrease in the mapping power MSOC and adjust the display of the mapping power MSOC only after the buffer time Tb has been reached, so as to display the mapping power MSOC in a milder manner.

To sum up, the electronic device and the battery power displaying method thereof provided in one or more embodiments of the disclosure may dynamically adjust the slope parameter according to the current state, and the adjusted slope parameter may be applied to convert the estimated power into the mapping power. Thereby, it is possible to customize a charging and discharging curve without changing the original firmware algorithm of the battery module, mitigate the dependence on battery suppliers, and improve the efficiency of product development. In addition, excessively rapid battery power change or power jumps/drops may be prevented, thereby increasing the stability of the system and providing users with a better user experience.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A battery power displaying method, adapted to an electronic device comprising a battery module, the battery power displaying method comprising:
obtaining estimated power of the battery module;
adjusting a slope parameter according to a charging and discharging state of the electronic device and the estimated power;
converting the estimated power into mapping power based on the slope parameter; and
displaying the mapping power on a user interface.

2. The battery power displaying method according to claim 1, wherein the estimated power is obtained by dividing a remaining capacity of the battery module by a full charge capacity of the battery module, and the step of converting the estimated power into the mapping power based on the slope parameter comprises:
multiplying the full charge capacity by the slope parameter to obtain a parameter capacity; and
dividing the remaining capacity by the parameter capacity to obtain the mapping power.

3. The battery power displaying method according to claim 1, wherein the step of adjusting the slope parameter according to the charging and discharging state of the electronic device and the estimated power comprises:
determining whether the battery module is being charged;
when the battery module is not being charged, determining whether the battery module has been fully charged during a previous charging period; and
when the battery module has been fully charged during the previous charging period, adjusting the slope parameter to a first slope.

4. The battery power displaying method according to claim 3, wherein the step of determining whether the battery module has been fully charged during the previous charging period comprises:
determining whether a power maintenance flag is set.

5. The battery power displaying method according to claim 4, further comprising:
when the battery module has been fully charged during a charging period, setting the power maintenance flag; and
when the battery module has not been fully charged during the charging period, resetting the power maintenance flag.

6. The battery power displaying method according to claim 3, wherein the step of adjusting the slope parameter according to the charging and discharging state of the electronic device and the estimated power further comprises:
when the battery module is being charged, determining whether the slope parameter is greater than a second slope, wherein the second slope is less than the first slope; and
if the slope parameter is determined as being greater than the second slope, gradually adjusting the slope parameter to the second slope.

7. The battery power displaying method according to claim 6, wherein the step of gradually adjusting the slope parameter to the second slope comprises:
determining an adjustment amount of the slope parameter based on a current average current of the battery module; and
subtracting the adjustment amount from the slope parameter at intervals of every predetermined time until the slope parameter equals the second slope.

8. The battery power displaying method according to claim 3, wherein the step of adjusting the slope parameter according to the charging and discharging state of the electronic device and the estimated power further comprises:
when the battery module has not been fully charged during the previous charging period, determining whether the estimated power is greater than or equal to predetermined power, and whether the battery module has been switched from a charging state to a discharging state; and
when the estimated power is greater than or equal to the predetermined power, and the battery module has been switched from the charging state to the discharging state, adjusting the slope parameter to a value obtained by dividing the remaining capacity of the battery module by the full charge capacity of the battery module.

9. The battery power displaying method according to claim 1, wherein the step of displaying the mapping power on the user interface comprises:
obtaining a current average current of the battery module;
determining a buffer time based on the average current;
determining whether a variation amount of the mapping power in a unit time is greater than a threshold value; and
if the variation amount of the mapping power in the unit time is determined as being greater than the threshold value, updating the mapping power displayed on the user interface by delaying the buffer time.

10. The battery power displaying method according to claim 9, wherein the step of updating the mapping power displayed on the user interface by delaying the buffer time comprises:
continuously increasing or decreasing a first percentage of a numerical value of the mapping power by a predetermined amount before the numerical value of the mapping power is changed at intervals of every buffer time, and sequentially updating the numerical value displayed on the user interface until the numerical value of the mapping power increases or decreases to a second percentage after the numerical value of the mapping power is changed.

11. An electronic device, comprising:
a battery module, comprising a battery cell group and a control circuit, wherein the control circuit is configured to calculate estimated power of the battery module;
a display device, configured to display a user interface;
a memory, configured to store a programming command; and
a processor, coupled to the battery module, the display device, and the memory and loading and executing the programming command to:
obtain the estimated power of the battery module from the control circuit;
adjust a slope parameter according to a charging and discharging state of the electronic device and the estimated power;
convert the estimated power into mapping power based on the slope parameter; and
display the mapping power on the user interface through the display device.

12. The electronic device according to claim 11, wherein the estimated power is obtained by dividing a remaining capacity of the battery module by a full charge capacity of the battery module, the processor multiplies the full charge capacity by the slope parameter to obtain a parameter capacity and divides the remaining capacity by the parameter capacity to obtain the mapping power.

13. The electronic device according to claim 11, wherein the processor determines whether the battery module is being charged, when the battery module is not being charged, the processor determines whether the battery module has been fully charged during a previous charging period, and when the battery module has been fully charged during the previous charging period, the processor adjusts the slope parameter to a first slope.

14. The electronic device according to claim 13, wherein the processor determines whether a power maintenance flag is set.

15. The electronic device according to claim 14, wherein when the battery module has been fully charged during a charging period, the processor sets the power maintenance flag, and when the battery module has not been fully charged during the charging period, the processor resets the power maintenance flag.

16. The electronic device according to claim 13, wherein when the battery module is being charged, the processor determines whether the slope parameter is greater than a second slope, wherein the second slope is less than the first slope; and
if the slope parameter is determined as being greater than the second slope, the processor gradually adjusts the slope parameter to the second slope.

17. The electronic device according to claim 16, wherein the processor determines an adjustment amount of the slope parameter based on a current average current of the battery module, and the processor subtracts the adjustment amount from the slope parameter at intervals of every predetermined time until the slope parameter equals the second slope.

18. The electronic device according to claim 13, wherein when the battery module has not been fully charged during the previous charging period, the processor determines whether the estimated power is greater than or equal to predetermined power, and whether the battery module has been switched from a charging state to a discharging state, and
when the estimated power is greater than or equal to the predetermined power, and the battery module has been switched from the charging state to the discharging state, the processor adjusts the slope parameter to a value obtained by dividing the remaining capacity of the battery module by the full charge capacity of the battery module.

19. The electronic device according to claim 11, wherein the processor obtains a current average current of the battery module from the control circuit, determines a buffer time based on the average current, and determines whether a variation amount of the mapping power in a unit time is greater than a threshold value, and if the variation amount of the mapping power in the unit time is determined as being greater than the threshold value, the processor updates the mapping power displayed on the user interface through the display device by delaying the buffer time.

20. The electronic device according to claim 19, wherein the processor continuously increases or decreases a first percentage of a numerical value of the mapping power by a predetermined amount before the numerical value of the mapping power is changed at intervals of every buffer time and sequentially updates the numerical value displayed on the user interface until the numerical value of the mapping power increases or decreases to a second percentage after the numerical value of the mapping power is changed.
